(19) United States
(12) Patent Application Publication
(10) Pub. No.: US 2024/0089146 A1
(43) Pub. Date: Mar. 14, 2024

(54) VEHICLE DIAGNOSTIC DEVICE FOR ELECTRIC VEHICLE

(71) Applicant: LG ENERGY SOLUTION, LTD., Seoul (KR)

(72) Inventor: Man-Hoo JANG, Daejeon (KR)

(73) Assignee: LG ENERGY SOLUTION, LTD., Seoul (KR)

(21) Appl. No.: 18/274,421

(22) PCT Filed: Nov. 16, 2022
(86) PCT No.: PCT/KR2022/018129

§ 371 Date: Jul. 26, 2023

(30) Foreign Application Priority Data
Nov. 23, 2021 (KR) 10-2021-0162803

(51) Int. Cl. H04L 12/40; B60R 16/023; G07C 5/08

(52) U.S. Cl. CPC H04L 12/40039; B60R 16/0231; G07C 5/0808; H04L 2012/40215; H04L 2012/40273

(57) ABSTRACT

A vehicle diagnostic device for an electric vehicle according to an aspect of the present disclosure includes a connector for attaching and detaching to/from a diagnostic controller area network (D-CAN) channel in a vehicle network system of the electric vehicle; a controller area network (CAN) transceiver connected to a first signal line and a second signal line of the D-CAN channel through the connector; a wakeup circuit connected to the first signal line or the second signal line through the connector; and a control circuit for changing from a sleep mode to a wakeup mode in response to an input of a first wakeup signal outputted by the CAN transceiver or a second wakeup signal outputted by the wakeup circuit in the sleep mode, and collect diagnosis data from the vehicle network system through the CAN transceiver in the wakeup mode.

### TECHNICAL FIELD

The present application claims priority to Korean Patent Application No. 10-2021-0162803 filed on Nov. 23, 2021 in the Republic of Korea, the disclosure of which is incorporated herein by reference.

The present disclosure relates to a vehicle diagnostic device for an electric vehicle, and more particularly, to an electronic device that can be connected to a D-CAN channel in a vehicle network system of an electric vehicle, and collects diagnosis data from at least one of electronic devices connected to another CAN channel in the electric vehicle when connected to the D-CAN channel.

### BACKGROUND ART

Recently, with the widespread use of electric vehicles, different types of electronic devices in the electric vehicles have diverse and advanced functions.

A vehicle network system of an electric vehicle is designed to support good and efficient communication between electronic devices of the electric vehicle, and basically Controller Area Network (CAN) communication is applied. The CAN communication refers to a message-based standard communication protocol designed to allow a micro controller or devices to communicate each other without a host computer in not only electric vehicles but also industrial and medical equipment.

The electronic devices in the electric vehicle may be categorized into a plurality of groups according to the use. Additionally, there is an additional electronic device that is detachably provided to the vehicle network system outside of the electric vehicle to diagnose the state of the electric vehicle. The vehicle network system provides a plurality of CAN communication channels (for example, P-CAN, B-CAN, C-CAN, D-CAN) and the electronic devices in the same group among the electronic devices inside and outside of the electric vehicle are connected in parallel through a specific communication channel among the plurality of CAN communication channels.

The vehicle network system outputs a wakeup pattern to at least one of the plurality of CAN communication channels according to the state of the electric vehicle. The electronic devices change from a sleep mode to a wakeup mode in response to the predetermined input wakeup pattern from the electric vehicle through the CAN communication channel to which the electronic devices are connected during the operation in the sleep mode.

In the electric vehicle, a relationship map is recorded between a plurality of states (for example, ignition On, ignition Off, charging) that the electric vehicle may experience and the CAN communication channels that will output the wakeup pattern in each state. For example, the ‘ignition On’ state may be set to output the wakeup pattern to all the CAN communication channels, and the ‘ignition Off’ state may be set to output the wakeup pattern to only the B-CAN.

The electric vehicle includes a diagnostic communication port referred to as ‘OBD-II’ in a predetermined area inside the interior room, and the D-CAN channel, one of the plurality of CAN communication channels in the vehicle network system, is connected to the diagnostic communication port. The electronic device (for example, a diagnosis scanner) as a diagnostic device for the electric vehicle is detachably provided to the diagnostic communication port through its connector and transmits a diagnosis request to the vehicle network system when coupled to the diagnostic communication port and collects input diagnosis data from the vehicle network system in response to the diagnosis request.

However, while the vehicle network system does not output the wakeup pattern to the D-CAN channel since the electric vehicle is in the specific state (for example, charging), even though the electronic device is connected to the diagnostic communication port, the electronic device cannot wake up from the sleep mode and collect diagnosis data associated with the electric vehicle.

### DISCLOSURE

### Technical Problem

The present disclosure is designed to solve the above-described problem, and therefore the present disclosure is directed to providing an electronic device that detects bias voltage of a signal line of a D-CAN channel, generates a wakeup signal, and automatically wakes up from a sleep mode by the wakeup signal to collect diagnosis data from an electric vehicle even though a wakeup pattern is not input to the D-CAN channel since the electric vehicle is in a specific state (for example, charging).

These and other objectives and advantages of the present disclosure may be understood by the following description and will be apparent from an embodiment of the present disclosure. In addition, it will be readily understood that the objectives and advantages of the present disclosure may be realized by the means set forth in the appended claims and a combination thereof.

### Technical Solution

A vehicle diagnostic device for an electric vehicle according to an aspect of the present disclosure includes a connector configured to attach and detach to/from a D-CAN channel in a vehicle network system of the electric vehicle; a CAN transceiver connected to a first signal line and a second signal line of the D-CAN channel through the connector; a wakeup circuit connected to the first signal line or the second signal line through the connector; and a control circuit configured to change from a sleep mode to a wakeup mode in response to an input of a first wakeup signal outputted by the CAN transceiver or a second wakeup signal outputted by the wakeup circuit in the sleep mode, and collect diagnosis data from the vehicle network system through the CAN transceiver in the wakeup mode.

The CAN transceiver may be configured to output the first wakeup signal to the control circuit in response to an input of a wakeup pattern from the D-CAN channel.

The wakeup circuit may be configured to output the second wakeup signal to the control circuit in response to an input voltage from the first signal line or the second signal line being larger than a reference voltage.

The wakeup circuit may include a voltage divider to split a first power source voltage from a power circuit in the electric vehicle to generate the reference voltage.

The wakeup circuit may include a comparator configured to output a high level voltage in response to the input voltage being larger than the reference voltage; and a signal transmission circuit configured to output a power source voltage from a power circuit in the electric vehicle as the second wakeup signal to the control circuit in response to the high level voltage.

The signal transmission circuit may include a first transistor including a gate connected to an output pin of the comparator, a source and a drain; a first resistor connected between the gate of the first transistor and the source of the first transistor; a second resistor connected between the source of the first transistor and a ground; a second transistor including a gate, a source connected to the power circuit and a drain connected to the control circuit; a third resistor connected between the gate of the second transistor and the source of the second transistor; and a fourth resistor connected between the gate of the second transistor and the drain of the first transistor.

The first transistor may be an N-channel MOSFET.

The second transistor may be a P-channel MOSFET.

The control circuit may include a voltage regulator configured to step-down a power source voltage from a power circuit in the electric vehicle to another voltage in response to the input of the first wakeup signal or the second wakeup signal; and a data processing unit configured to operate in the wakeup mode in response to the input of the power source voltage from the voltage regulator in the sleep mode.

The control circuit may be configured to change from the sleep mode to the wakeup mode in response to the input of the first wakeup signal or the second wakeup signal maintaining for a predetermined time in the sleep mode.

The control circuit may be configured to change from the wakeup mode to the sleep mode in response to the second wakeup signal being not inputted for a predetermined time after the change from the sleep mode to the wakeup mode by the second wakeup signal.

### Advantageous Effects

According to at least one of the embodiments of the present disclosure, it is possible to detect bias voltage of the signal line of the D-CAN channel, generate a wakeup signal, and automatically wake up from a sleep mode by the wakeup signal to collect diagnosis data from the electric vehicle even though a wakeup pattern is not input to the D-CAN channel since the electric vehicle is in a specific state (for example, charging).

The effects of the present disclosure are not limited to the above-mentioned effects, and these and other effects will be clearly understood by those skilled in the art from the appended claims.

### DESCRIPTION OF DRAWINGS

The accompanying drawings illustrate an exemplary embodiment of the present disclosure, and together with the following detailed description, serve to provide a further understanding of the technical aspect of the present disclosure, and thus the present disclosure should not be construed as being limited to the drawings.

FIG. 1 is a diagram exemplarily showing an electric vehicle related to the present disclosure and a vehicle diagnostic device detachably provided to the electric vehicle outside of the electric vehicle.

FIG. 2 is a diagram schematically showing the configuration of the vehicle diagnostic device shown in FIG. 1.

FIG. 3 is a timing chart referenced in describing the operation of a wakeup circuit of FIG. 2.

### BEST MODE

Hereinafter, exemplary embodiments of the present disclosure will be described in detail with reference to the accompanying drawings. Prior to the description, it should be understood that the terms or words used in the specification and the appended claims should not be construed as being limited to general and dictionary meanings, but rather interpreted based on the meanings and concepts corresponding to the technical aspect of the present disclosure on the basis of the principle that the inventor is allowed to define the terms appropriately for the best explanation.

Therefore, the embodiments described herein and the illustrations shown in the drawings are just an exemplary embodiment of the present disclosure, but not intended to fully describe the technical aspect of the present disclosure, so it should be understood that a variety of other equivalents and modifications could have been made thereto at the time that the application was filed.

The terms including the ordinal number such as “first”, “second” and the like, are used to distinguish one element from another among various elements, but not intended to limit the elements.

Unless the context clearly indicates otherwise, it will be understood that the term “comprises” when used in this specification, specifies the presence of stated elements, but does not preclude the presence or addition of one or more other elements. Additionally, the term “control unit” as used herein refers to a processing unit of at least one function or operation, and may be implemented in hardware and software either alone or in combination.

In addition, throughout the specification, it will be further understood that when an element is referred to as being “connected to” another element, it can be directly connected to the other element or intervening elements may be present.

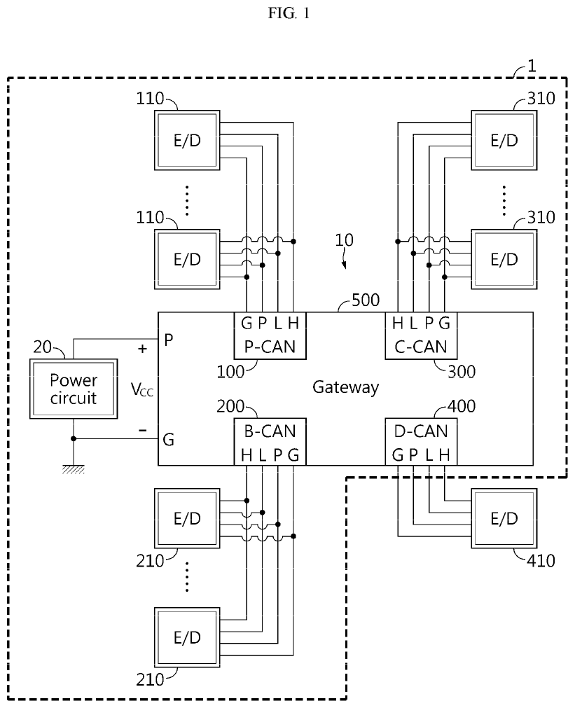

FIG. 1 is a diagram exemplarily showing an electric vehicle 1 related to the present disclosure and a vehicle diagnostic device 410 detachably provided to the electric vehicle 1 outside of the electric vehicle 1.

Referring to FIG. 1, the electric vehicle 1 includes a vehicle network system 10, electronic devices 110, 210, 310 and a power circuit 20.

The vehicle network system 10 includes a P(Powertrain)-CAN channel 100, a B(Body)-CAN channel 200, a C(Chassis)-CAN channel 300, a D(Diagnostic)-CAN channel 400 and a gateway 500.

Each of the electronic devices 110, 210, 310 is connected to one of the P-CAN channel 100, the B-CAN channel 200, the C-CAN channel 300 and the D-CAN channel 400. From the perspective of the vehicle network system 10, each of electronic devices 110, 210, 310, 410 may be referred to as a ‘node’. Two or more electronic devices may be connected in parallel to each of the P-CAN channel 100, the B-CAN channel 200, the C-CAN channel 300 and the D-CAN channel 400.

The power circuit 20 is configured to supply a power source voltage V_{CC} required for the operation of the vehicle network system 10 and the electronic devices 110, 210, 310. For example, the power circuit 20 may include a battery (for example, a lead acid battery) and a voltage regulator to convert the output voltage of the battery to the power source voltage V_{CC} of a predetermined constant voltage value (for example, 12 [V]).

The P-CAN channel 100 is provided for the communication with the electronic devices 110 related to the driving function of the electric vehicle 1, for example, an engine, a steering wheel, an electric motor and an electronic pedal.

The B-CAN channel 200 is provided for the communication with the electronic devices 210 irrelevant to the driving function of the electric vehicle 1, for example, a smart key module, a light, an electronic door, a sunroof, a wiper, an airbag, an air conditioner and a power window.

The C-CAN channel 300 is provided for the communication with the electronic devices 310 responsible for the function related to the chassis of the electric vehicle 1, for example, a cluster and a Yaw Rate Sensor (YRS), and may support higher communication speed than the B-CAN.

The D-CAN channel 400 is used to transmit a diagnosis request from the vehicle diagnostic device 410 disposed outside of the electric vehicle 1 to at least one of the electronic devices 110, 210, 310 disposed inside of the electric vehicle 1, and transmit and receive diagnosis data output from the electronic devices 110, 210, 310 in response to the diagnosis request. Hereinafter, to distinguish the vehicle diagnostic device 410 from the electronic devices 110, 210, 310, the vehicle diagnostic device 410 is referred to as a ‘vehicle diagnostic device’.

The gateway 500 is the crucial component of the vehicle network system 10, and takes responsibility for message exchange, communication path setting and communication speed control functions between the P-CAN channel 100, the B-CAN channel 200, the C-CAN channel 300 and the D-CAN channel 400. The gateway 500 relays the communication from any one of the P-CAN channel 100, the B-CAN channel 200, the C-CAN channel 300 or the D-CAN channel 400 to at least one of the other channels. For example, when the diagnosis request from the vehicle diagnostic device 410 is received by the gateway 500 through the D-CAN channel 400, the gateway 500 identifies the electronic devices 110, 210, 310 in the electric vehicle 1 associated with the received diagnosis request, and inputs the corresponding diagnosis request to the CAN channels 100, 200, 300 connected to the identified electronic devices 110, 210, 310. Then, the identified electronic devices 110, 210, 310 receive the diagnosis request through the CAN channels 100, 200, 300 to which the electronic devices 110, 210, 310 are connected, and returns the diagnosis data being inquired in the received diagnosis request to the CAN channels 100, 200, 300 to which the electronic devices 110, 210, 310 are connected. The returned diagnosis data is inputted to the vehicle diagnostic device 410 through the D-CAN channel 400 via the gateway 500. The diagnosis data indicates the state of at least one component identified by the diagnosis request among the plurality of components mounted in the electric vehicle 1. For example, the diagnosis request inquiring about a State Of Health (SOH) of a battery pack of the electric vehicle 1 is transmitted to a Battery Management System (BMS), one of the electronic devices 110, 310 connected to the P-CAN channel 100 or the C-CAN channel 300, through the gateway 500. In response to the diagnosis request, the BMS performs the calculation function of the SOH of the battery pack, and transmits a message indicating the calculated SOH as the diagnosis data to the gateway 500.

The gateway 500 is connected to each of the power circuit 20 and the ground (for example, the chassis) to provide the input power source voltage V_{CC} from the power circuit to between a power pin P and a ground pin G of each of the P-CAN channel 100, the B-CAN channel 200, the C-CAN channel 300 and the D-CAN channel 400.

In FIG. 1, the symbols H, L, P and G refer to a first signal line, a second signal line, a ground line and a power line and pins connected to them. Each CAN channel is a bundle of the four electrical lines, i.e., the first signal line (CAN-H line, H), the second signal line (CAN-L line, L), the power line P and the ground line G. The first signal line H and the second signal line L are used for the communication of the vehicle diagnostic device 410, and a pair of the first signal line H and the second signal line L may be referred to as a ‘CAN-bus’. The ground line feeds a ground voltage (the potential of the chassis) of the electric vehicle 1. The power line P is connected to the output terminal of the power circuit 20 to feed the power source voltage V_{CC}. The power source voltage V_{CC} is used to operate the electronic devices 110, 210, 310, 410. For reference, in the CAN communication, the first signal line H is typically represented as ‘CAN-H’, ‘CAN-high’ or ‘CAN+’, and the second signal line L is typically represented as ‘CAN-L’, ‘CAN-low’ or ‘CAN−’.

In response to the electric vehicle 1 being in a first state (for example, ignition On), the gateway 500 may output the predetermined wakeup pattern through the first signal line H and the second signal line L of all the P-CAN channel 100, the B-CAN channel 200, the C-CAN channel 300 and the D-CAN channel 400. For example, the wakeup pattern may be based on ISO 11898-2.

In response to the electric vehicle 1 being in a second state (for example, ignition Off), the gateway 500 may stop the output of the predetermined wakeup pattern through the CAN-bus of all the P-CAN channel 100, the B-CAN channel 200, the C-CAN channel 300 and the D-CAN channel 400.

In response to the electric vehicle 1 being in a third state (for example, ignition preparation, charging), the gateway 500 stops the output of the predetermined wakeup pattern to the first signal line H and the second signal line L of at least one CAN channel among the P-CAN channel 100, the B-CAN channel 200 and the C-CAN channel 300, and instead, may output the bias voltage of the predetermined constant voltage value (for example, 2.5V) to at least one of the first signal line H or the second signal line L of the corresponding CAN channel. The ignition preparation state may be a state of preparation for the ignition On state of the electric vehicle 1 in response to the smart key module, one of the electronic devices 210 connected to the B-CAN channel 200, detecting the smart key approaching within a predetermined distance from the electric vehicle 1.

In response to the electric vehicle 1 being in the third state, the gateway 500 may output the bias voltage of the predetermined constant voltage value to at least one of the first signal line H or the second signal line L of the D-CAN channel 400.

During the output of the predetermined wakeup pattern to at least one of the P-CAN channel 100, the B-CAN channel 200 or the C-CAN channel 300, the gateway 500 may output the bias voltage of the predetermined constant voltage value to at least one of the first signal line H or the second signal line L of the D-CAN channel 400.

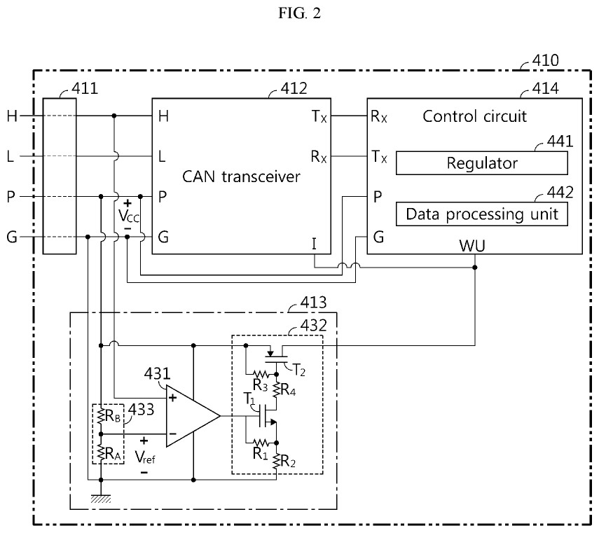

FIG. 2 is a diagram schematically showing the configuration of the vehicle diagnostic device 410 shown in FIG. 1.

Referring to FIG. 2, the vehicle diagnostic device 410 includes a connector 411, a CAN transceiver 412, a wakeup circuit 413 and a control circuit 414.

The connector 411 may be attached and detached to/from the 4 pins (H, L, P, G) of the D-CAN channel 400 in the vehicle network system 10 of the electric vehicle 1. Each of the CAN transceiver 412, the wakeup circuit 413 and the control circuit 414 is connected to at least one of the 4 pins (H, L, P, G) through the connector 411.

The CAN transceiver 412 is connected to the first signal line H and the second signal line L through the connector 411 to output a first wakeup signal from the wakeup pin I in response to a change in voltage difference between the first signal line H and the second signal line L being matched to the predetermined wakeup pattern. The wakeup pin WU of the control circuit 414 is connected to the wakeup pin I of the CAN transceiver 412. The control circuit 414 changes from the sleep mode to the wakeup mode in response to the first wakeup signal being input to the wakeup pin WU in the sleep mode. After the wake up, the control circuit 414 may communicate with the electric vehicle 1 using the CAN transceiver 412. The signal output pin Tx of the control circuit 414 is connected to the signal input pin Rx of the CAN transceiver 412, and the signal input pin Rx of the control circuit 414 is connected to the signal output pin Tx of the CAN transceiver 412. The CAN transceiver 412 transmits the message received through the first signal line H and the second signal line L to the signal input pin Rx of the control circuit 414 through the signal output pin Tx of the CAN transceiver 412. The CAN transceiver 412 receives the message outputted from the signal output pin Tx of the control circuit 414 through the signal input pin Rx of the CAN transceiver 412, and transmits the received message to the gateway 500 through the first signal line H and the second signal line L.

The wakeup circuit 413 is configured to wake up the control circuit 414 independently of the function of the CAN transceiver 412 to wake up the control circuit 414. Specifically, the wakeup circuit 413 is configured to output a second wakeup signal in response to the voltage of the first signal line H or the second signal line L of the D-CAN channel 400 being larger than the reference voltage V_{ref} while the CAN transceiver 412 cannot output the first wakeup signal to the control circuit 414 since the wakeup pattern is not input through the D-CAN channel 400. The output pin of the wakeup circuit 413 is connected to the wakeup pin WU of the control circuit 414. The control circuit 414 changes from the sleep mode to the wakeup mode in response to the second wakeup signal input to the wakeup pin WU in the sleep mode.

Each of the first wakeup signal and the second wakeup signal may refer to a high level voltage that is equal to or larger than a predetermined voltage value.

The wakeup circuit 413 includes a comparator 431 and a signal transmission circuit 432, and may further include a voltage divider 433.

The comparator 431 include an input pin (+), an input pin (−) and an output pin. The voltage of the first signal line H is input to the input pin (+) through the connector 411. FIG. 2 shows the first signal line H connected to the input pin (+). The reference voltage V_{ref} that is equal to or larger than the predetermined voltage value (for example, 2V) is input to the input pin (−). The reference voltage V_{ref} is less than the bias voltage output to the first signal line H. In response to the input voltage of the input pin (+) being larger than the input voltage V_{ref} of the input pin (−), the comparator 431 outputs the high level voltage of the predetermined voltage value from the output pin. The comparator 431 may operate using the power source voltage V_{CC}. The high level voltage output from the output pin of the comparator 431 may be equal to the power source voltage V_{CC}. The comparator 431 outputs a low level voltage of a predetermined voltage value (for example, 0 [V]) from the output pin in response to the input voltage of the input pin (+) being smaller than the input voltage of the input pin (−). The low level voltage output from the output pin of the comparator 431 may be equal to the ground voltage.

FIG. 2 shows the signal transmission circuit 432 including a first resistor R₁, a second resistor R₂, a first transistor T₁, a third resistor R₃, a fourth resistor R₄, and a second transistor T₂.

The gate of the first transistor T₁ is connected to the output pin of the comparator 431. The first resistor R₁ is connected between the gate of the first transistor T₁ and the source of the first transistor T₁. The second resistor R₂ is connected between the source of the first transistor T₁ and the ground. The source of the second transistor T₂ is connected to the power line P. The drain of the second transistor T₂ is connected to the wakeup pin WU of the control circuit 414. The third resistor R₃ is connected between the gate of the second transistor T₂ and the source of the second transistor T₂. The fourth resistor R₄ is connected between the gate of the second transistor T₂ and the drain of the first transistor T₁. The first transistor T₁ may be an N-channel MOSFET. The second transistor T₂ may be a P-channel MOSFET. During the output of the high level voltage from the output pin of the comparator 431, the first transistor T₁ is in an on state. While the first transistor T₁ is in the on state, an electric current flows through the third resistor R₃, the fourth resistor R₄, the first transistor T₁ and the second resistor R₂, and accordingly, voltage across the third resistor R₃ is inputted as gate-source voltage of the second transistor T₂, and the second transistor T₂ is in the on state. While the second transistor T₂ is in the on state, the power source voltage V_{CC} is inputted to the wakeup pin WU of the control circuit 414 as the second wakeup signal.

The voltage divider 433 includes a resistor R_{A} and a resistor R_{B}. The power source voltage V_{CC} is split by a resistance ratio between the resistor R_{A} and the resistor R_{B} and the reference voltage V_{ref} is inputted to the input pin (−). That is, V_{ref}=V_{CC}×R_{A}/(R_{A}+R_{B}). Although FIG. 2 shows the reference voltage V_{ref} provided from the power source voltage V_{CC}, the output voltage of an accumulator such as a coin cell may be used for the reference voltage V_{ref}.

The control circuit 414 may be configured to change from the sleep mode to the wakeup mode in response to the input of the first wakeup signal or the second wakeup signal maintaining for a predetermined time in the sleep mode.

The control circuit 414 includes a voltage regulator 441 and a data processing unit 442. The voltage regulator 441 may be configured to step-down the power source voltage V_{CC} input to the power pin P of the control circuit 414 to a voltage (for example, 5 [V]) in response to the first wakeup signal or the second wakeup signal being input to the wakeup pin WU. The data processing unit 442 is configured to change from the sleep mode to the wakeup mode when activated (powered) upon receiving the voltage generated from the power source voltage V_{CC} by the voltage regulator 441. The data processing unit 442 may be implemented in hardware using at least one of application specific integrated circuits (ASICs), digital signal processors (DSPs), digital signal processing devices (DSPDs), programmable logic devices (PLDs), field programmable gate arrays (FPGAs), microprocessors or electrical units for performing other functions.

After the control circuit 414 changes from the sleep mode to the wakeup mode by the first wakeup signal, in response to the first wakeup signal being not inputted for a predetermined time, the control circuit 414 may change from the wakeup mode to the sleep mode. Of course, even in a situation in which the first wakeup signal is not inputted for more than the predetermined time, when the second wakeup signal is being inputted, the control circuit 414 may be kept in the wakeup state.

After the control circuit 414 changes from the sleep mode to the wakeup mode by the second wakeup signal, in response to the second wakeup signal being not inputted for the predetermined time, the control circuit 414 may change from the wakeup mode to the sleep mode. Of course, even in a situation in which the second wakeup signal is not inputted for more than the predetermined time, when the first wakeup signal is being inputted, the control circuit 414 may be kept in the wakeup state.

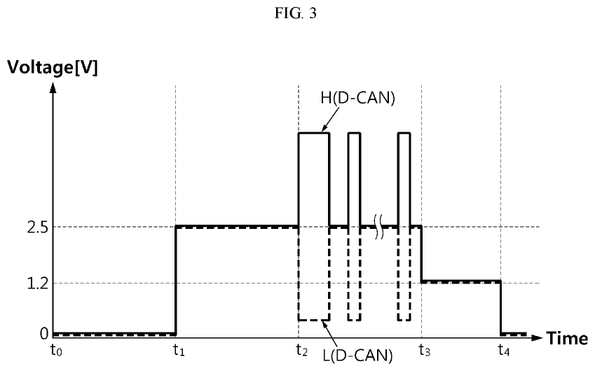

FIG. 3 is a timing chart referenced in describing the operation of the wakeup circuit 413 of FIG. 2.

In the CAN communication, a state in which voltage of each of the first signal line H and the second signal line L is equal to the bias voltage may be referred to as a ‘recessive state’. Meanwhile, a state in which the voltage (for example, 3.5 to 5 V) of the first signal line H is higher than the bias voltage and the voltage (for example, 0 to 1.5 V) of the second signal line L is lower than the bias voltage is referred to as a ‘dominant state’. In the dominant state, a voltage difference between the first signal line H and the second signal line L may be about 2 to 5 V. The communication between the electric vehicle 1 and the vehicle diagnostic device 410 using the D-CAN channel 400 is performed by time-series changes of the recessive state and the dominant state.

Referring to FIGS. 1 to 3, as shown, when the electric vehicle 1 is in the second state for a period of time of from time t₀ to time t₁, not only the D-CAN channel 400 but also the P-CAN channel 100, the B-CAN channel 200 and the C-CAN channel 300 are inactivated, that is to say, the voltage of the first signal line H and the second signal line L is 0 V.

When the electric vehicle 1 changes from the second state to the third state at the time t₁, the state is shifted to the recessive state of 2.5 V in which the first signal line H and the second signal line L of the D-CAN channel 400 is larger than the reference voltage V_{ref}, and is maintained until time t₂. When the time t₂ is the time after the lapse of a predefined time from the time t₁ for wakeup, the control circuit 414 changes from the sleep mode to the wakeup mode at the time t₂.

The control circuit 414 may collect the diagnosis data via communication with the electric vehicle 1 using the CAN transceiver 412 by the operation in the wakeup mode for a period of time of from time t₂ to time t₃.

From the time t₃ when the state is shifted to the recessive state of 1.2 V in which the first signal line H and the second signal line L of the D-CAN channel 400 is smaller than the reference voltage V_{ref}, the wakeup circuit 413 stops the output of the second wakeup signal. The recessive state of 1.2 V is kept for a few seconds to a few minutes from the time when the electric vehicle 1 changes from the third state to the second state, and is shifted to the recessive state of 0V at time t₄. The recessive state of 1.2 V relies on the voltage difference between the electric vehicle 1 and the CAN bus (H, L) of the D-CAN channel 400. The control circuit 414 changes from the wakeup mode to the sleep mode again in response to the recessive state in which the first signal line H and the second signal line L is smaller than the reference voltage V_{ref} being maintained for the predetermined time or more during the operation in the wakeup mode.

While the present disclosure has been hereinabove described with regard to a limited number of embodiments and drawings, the present disclosure is not limited thereto and it is obvious to those skilled in the art that various modifications and changes may be made thereto within the technical aspect of the present disclosure and the appended claims and equivalents thereof.

Additionally, as many substitutions, modifications and changes may be made to the present disclosure described hereinabove by those skilled in the art without departing from the technical aspect of the present disclosure, the present disclosure is not limited by the above-described embodiments and the accompanying drawings, and all or some of the embodiments may be selectively combined to allow various modifications.

### DESCRIPTION OF REFERENCE NUMERALS

| | |
|---|---|
| 1: Electric vehicle | |
| 10: Vehicle network system | 20: Power circuit |
| 100: P-CAN channel | 200: B-CAN channel |
| 300: C-CAN channel | 400: D-DAN channel |
| 500: Gateway | |
| 110, 210, 310, 410: Electronic device | |
| 411: Connector | 412: CAN transceiver |
| 413: Wakeup circuit | 414: Control circuit |

1. A vehicle diagnostic device for an electric vehicle, the vehicle diagnostic device comprising:
a connector configured to be attached to or detached from a diagnostic controller area network (D-CAN) channel in a vehicle network system of the electric vehicle;
a controller area network (CAN) transceiver connected to a first signal line and a second signal line of the D-CAN channel through the connector;
a wakeup circuit connected to the first signal line or the second signal line through the connector; and
a control circuit configured to:
change from a sleep mode to a wakeup mode in response to an input of a first wakeup signal outputted by the CAN transceiver or a second wakeup signal outputted by the wakeup circuit in the sleep mode, and
collect diagnosis data from the vehicle network system through the CAN transceiver in the wakeup mode.

2. The vehicle diagnostic device according to claim 1, wherein the CAN transceiver is configured to output the first wakeup signal to the control circuit in response to an input of a wakeup pattern from the D-CAN channel.

3. The vehicle diagnostic device according to claim 1, wherein the wakeup circuit is configured to output the second wakeup signal to the control circuit in response to an input voltage from the first signal line or the second signal line being larger than a reference voltage.

4. The vehicle diagnostic device according to claim 3, wherein the wakeup circuit includes a voltage divider to split a first power source voltage from a power circuit provided in the electric vehicle to generate the reference voltage.

5. The vehicle diagnostic device according to claim 3, wherein the wakeup circuit includes:
a comparator configured to output a high level voltage in response to the input voltage being larger than the reference voltage; and
a signal transmission circuit configured to output a power source voltage from a power circuit provided in the electric vehicle, as the second wakeup signal, to the control circuit, in response to the high level voltage.

6. The vehicle diagnostic device according to claim 5, wherein the signal transmission circuit includes:
a first transistor including a gate connected to all of an output pin of the comparator, a source and a drain;
a first resistor connected between the gate of the first transistor and the source of the first transistor;
a second resistor connected between the source of the first transistor and a ground;
a second transistor including a gate, a source connected to the power circuit and a drain connected to the control circuit;
a third resistor connected between the gate of the second transistor and the source of the second transistor; and
a fourth resistor connected between the gate of the second transistor and the drain of the first transistor.

7. The vehicle diagnostic device according to claim 6, wherein the first transistor is an N-channel metal-oxide-semiconductor field-effect transistor (MOSFET), and
wherein the second transistor is a P-channel MOSFET.

8. The vehicle diagnostic device according to claim 1, wherein the control circuit includes:
a voltage regulator configured to step-down a power source voltage from a power circuit in the electric vehicle to another voltage in response to the input of the first wakeup signal or the second wakeup signal; and
a data processing unit configured to operate in the wakeup mode in response to the input of the power source voltage from the voltage regulator in the sleep mode.

9. The vehicle diagnostic device according to claim 1, wherein the control circuit is further configured to change from the sleep mode to the wakeup mode in response to the input of the first wakeup signal or the second wakeup signal maintaining for a predetermined time in the sleep mode.

10. The vehicle diagnostic device according to claim 1, wherein the control circuit is further configured to change from the wakeup mode to the sleep mode in response to the second wakeup signal being not inputted for a predetermined time after the change from the sleep mode to the wakeup mode by the second wakeup signal.
